(19) United States
(12) Patent Application Publication
(10) Pub. No.: US 2023/0332292 A1
(43) Pub. Date: Oct. 19, 2023

(54) CVD REACTOR WITH TEMPERATURE-CONTROLLABLE GAS INLET REGION

(71) Applicant: AIXTRON SE, Herzogenrath (DE)

(72) Inventor: Philip HENS, Obermichelbach (DE)

(21) Appl. No.: 18/024,925

(22) PCT Filed: Aug. 31, 2021
(86) PCT No.: PCT/EP2021/074000

§ 371 Date: Mar. 6, 2023

(30) Foreign Application Priority Data
Sep. 7, 2020 (DE) 10 2020 123 326.4

(51) Int. Cl. C23C 16/458; C23C 16/455; C23C 16/48; C23C 16/32; H01L 21/687; H01L 21/67

(52) U.S. Cl. CPC C23C 16/4585; C23C 16/4584; C23C 16/45508; C23C 16/483; C23C 16/325; H01L 21/68771; H01L 21/67109; H01L 21/68764

(57) ABSTRACT

A CVD reactor includes a reactor housing, a susceptor that forms a floor of a process chamber, a gas inlet member with at least one gas inlet region, a heating device arranged under the susceptor for producing a difference in temperature between the main body of the susceptor and a ceiling of the process chamber, substrate carriers located at a distance from the gas inlet member in a direction of flow, and flow zone plates arranged between the gas inlet member and each of the substrate carriers. For each flow zone plate, a flow zone temperature of a surface of the flow zone plate which faces the process chamber can be set by respectively selecting or setting a heat transfer medium. For individually controlling each of the flow zone temperatures, the flow zone plates can be exchanged with other flow zone plates with different flow transfer properties.

### RELATED APPLICATIONS

This application is a National Stage under 35 USC 371 of and claims priority to International Application No. PCT/EP2021/074000, filed 31 Aug. 2021, which claims the priority benefit of DE Application No. 10 2020 123 326.4, filed 7 Sep. 2020.

### FIELD OF THE INVENTION

The invention relates to a CVD reactor with a susceptor, which is arranged in a reactor housing and forms a floor of a process chamber, a gas inlet member which has at least one gas inlet region, with a heating device which is arranged under the susceptor for creating a temperature difference between the main body and a process chamber ceiling, with a number of substrate carriers at a distance from the gas inlet member in a flow direction, each for receiving substrates that are to be coated, and with a number of flow zone plates arranged between the gas inlet member and the substrate carriers, wherein a flow zone temperature of the surface of the flow zone plate facing the process chamber is adjustable in each case by the selection or adjustment of a heat transfer medium, wherein the heat transfer media arranged immediately upstream in the flow direction of each of the multiple substrate carriers are adjustable in each case independently of the adjacent heat transfer media.

The invention further relates to a method for depositing in particular doped layers on substrates in a CVD reactor, wherein a process gas is fed into a gas inlet member, and from a gas inlet region of the gas inlet member passes into a process chamber, the floor of which is formed by a susceptor, which is heated by a heating device arranged under the susceptor in such manner that a temperature difference is created between a process chamber ceiling and the susceptor, wherein the process gas flows in a flow direction towards the substrates supported on substrate carriers and is pre-decomposed above flow zone plates in a flow zone of the process chamber between gas inlet member and substrate carrier, and products of decomposition form the layer, wherein flow zone temperatures of the surfaces in each case facing the process chamber of the flow zone plates arranged immediately upstream in the flow direction of one of the substrate carriers are adjusted by the selection or setting of a heat transfer medium arranged in each case between a main body of the susceptor and the flow zone plate.

### BACKGROUND

A species-related CVD reactor and a species-related method are described in DE 10 2014 104 218 A1. Flow zone plates are located between a gas inlet member and substrate carriers arranged on a circular arc line around the gas inlet member, wherein each flow zone plate adjoins two substrate carriers. The flow zone plates are supported on a main body of the susceptor. A horizontal gap extends between main body and flow zone plate, into which a heat transfer gas can be fed in order to influence the heat transfer from the susceptor heated by a heating device to a cooled process chamber ceiling by a variation of the thermal conductivity of the gas. The flow zone temperature can be adjusted by means of this influence.

In DE 103 23 085 A1, a CVD reactor is described. Substrates are positioned on a multipart susceptor and are coated with a semiconductor layer. For this purpose, process gases consisting of an organometallic III-component and a V-component are introduced into the process chamber through a gas inlet member. This takes place with the aid of a carrier gas, for example hydrogen. The susceptor is heated from below up to temperatures between 500 and over 1,000° C. Since the process chamber ceiling is actively cooled, a vertical temperature gradient forms inside the susceptor. The temperature of the surface of the substrate carrier and the temperature of the surface of a flow zone plate are determined by permanent vertical flow of heat from the heating device underneath the susceptor to the cooling device above the susceptor. Thus, the heat transfer properties between the main body and the substrate carrier and/or the flow zone plate are significant for the surface temperature of the substrate carrier and of the substrate supported on the substrate carrier as well as the surface temperature of the flow zone. The flow zone plate is located at a distance vertically from the main body. Consequently a horizontal gap is created, which forms a heat transfer barrier. In the prior art, the surface temperature of the flow zone plate depends on the presettable vertical gap width of the horizontal gap.

DE 10 2010 000 554 A1 describes a MOCVD reactor, in which the thermal conductivity coupling between a ceiling panel and a thermal dissipation member is different locally, and in particular radially. According to this arrangement, a purge gas flows through the horizontal gap between ceiling panel and thermal dissipation member. The purge gas may be formed from a mixture of gases with differing thermal conductivity capabilities, for example hydrogen and nitrogen.

DE 10 2011 002 146 A1 describes the influence of the flow zone temperature and gas phase reactions within the flow zone on the layer growth in the growth zone adjacent to the flow zone in flow direction, in which the substrates are arranged.

U.S. Pat. No. 6,001,183, or DE 36 33 386 A1, also describes a substrate holder with channels through which a gas-phase heat transfer medium flows.

DE 10 2006 018 514 A1 describes an apparatus and a method for controlling the surface temperature of a substrate in a process chamber, wherein it is provided in particular that a heat transfer medium is fed into a horizontal gap, which forms a gas cushion, on which a substrate carrier rotates.

Particularly when depositing doped SiC layers, small changes in the flow zone temperatures have a considerable influence on the insertion of the dopant. The consequence of this is that in a deposition process in which one layer is deposited simultaneously on a number of substrates that are supported on substrate carriers assigned to them, minor deviations of the flow zone temperatures from a target value result in significant differences in the dopant concentrations in the deposited layers. As a result of tolerances in the gas inlet regions of the gas inlet member and other components of the susceptor, differences arise in the flow zone temperatures of adjacent flow zones. The consequence of this is that the layers deposited during a deposition process may have dopant concentrations that differ from each other.

### SUMMARY OF THE INVENTION

The object underlying the invention is to present measures with which the flow zone temperature can be adjusted for each substrate and/or each and/or each substrate carrier individually.

Whereas in the prior art the flow zone temperature can only be adjusted by gas flows, it is possible according to the invention to react to, for example, tolerance-induced deviations of the flow temperatures, particularly in individual, possibly adjacent flow zones, from a target temperature or average temperature due to the fact that the transport of heat to the flow zone plate can also be preset individually in each flow zone. The heat transfer media may be elements or properties that are physically assigned to the flow zone. The thermal transfer media may be adjusted before the deposition process is carried out, for example through the use of suitable flow zone plates or by individually selecting the gap height of the horizontal gap. However, this may also take place during the performance of the deposition process, by feeding an individually mixed heat transfer gas into the horizontal gap. For this purpose, an inlet opening for a heat transfer gas is provided upstream of each substrate carrier. This is the outflow from a feeder channel, with which an individually mixed heat transfer gas is fed into the horizontal gap. In a gas mixing device, a multiplicity of mass flow controllers is provided, wherein at least each feeder channel has at least one mass flow controller assigned to it individually. With this at least one mass flow controller, an individually mixed heat transfer gas can be fed into the respective feeder channel. In this way, it is possible to adjust the surface temperatures of the flow zone plates individually for each flow zone located in front of a substrate carrier. It is provided according to the invention that the number of flow zone plates is equal to the number of substrate carriers. The flow zone temperature may be adjusted with passive adjustment means, for example the spacer elements. The heat transfer gas may be fed into the horizontal gap, the height of which is adjusted with the spacer element. Alternatively, a heat transfer element may also be inserted between flow zone plate and main body. The heat transfer element has an individual thermal conductivity capability. To increase the flow zone temperature, the heat transfer element may be replaced by a different heat transfer element with a higher thermal conductivity capability. To reduce the flow zone temperature, the heat transfer element may be replaced by another with a lower thermal conductivity capability. The height of the horizontal gap may be adjusted individually by various spacer elements, which define the height of the horizontal gap. The horizontal gap may even by zero, in that the flow zone plate rests directly on the main body. Spacer elements can create a gap height of 0.5 mm, 0.75 mm, 1 mm etc. But it is also possible to create very narrow horizontal gaps, which have a smaller gap height than 0.5 mm. Thus for example, compared with a gap height of 0 mm, a 0.7 mm gap height produces a temperature difference of about 20 K. When the method or the apparatus is used to deposit silicon carbide, this gap height variation can influence the dopant level by as much as 50%. Fine tuning is possible with the selection of the gas mixture that flows through the horizontal gap. A CVD reactor constructed according to the invention may include a multiplicity of flow zone plates that are of the same structure as each other, wherein individual flow zone plates, in particular two of said plates differ from one another in terms of their heat transfer properties. It is also provided that at least two flow zone plates differ from each other in terms of their material thickness or in terms of spacer elements. But flow zone plates of the kind according to the invention may also be designed identically to each other. Then, it is provided that the gap heights differ, for which purpose spacer elements with different thickness are arranged under each of two differing flow zone plates. It may further be provided that heat transfer elements that have heat transfer properties differing from each other are arranged between main body and flow zone plate at two different flow zones. The method according to the invention provides in particular that individual flow zone plates may be replaced with other flow zone plates that have other heat transfer properties, or that spacer elements or heat transfer elements are replaced before the deposition process.

In the embodiments described previously, passive measures for adapting the flow zone temperatures to the respective substrate carrier are implemented. A further aspect of the invention relates to active temperature influencing elements. These temperature influencing elements may be locally arranged heating devices. Flow zone heating devices of such kind may be laser heaters, for example a laser diode heater. But flow zone heating devices may also be local resistance heaters. The flow zone heating devices may be attached immovably to the housing of the CVD reactor or to the process chamber ceiling. If a flow zone heating device is attached to the housing outside of the process chamber, the process chamber ceiling may have an opening through which a laser beam generated by the flow zone heating device passes through the opening onto the surface of the flow zone plate that faces towards the process chamber. The impingement point of the laser beam is on the flow zone plate. At the point where the laser beam impinges on the flow zone plate, the surface temperature thereof rises. The laser, which is the flow zone heating device, may be synchronized with the rotating movement of the susceptor by a control device, so that the laser beam can be switched on and off, and only selected flow zone plates are heated locally. However, it is also provided that a flow zone plate or a region of a flow zone plate has a resistance heater. A resistance heater of such kind may be integrated in the main body of the susceptor. It may also be integrated in the flow zone plate. But the resistance heater may also be arranged in the gap between flow zone plate and main body of the susceptor. It is further provided that a flow zone heating device may be arranged underneath the susceptor. This flow zone heating device may also be equipped with a laser, with which the underside of the susceptor can be heated locally. A flow zone heating device of such kind is able to rotate together with the susceptor. The heating device may be arranged on the end of an arm, for example, which is attached to the support member and rotates together with the susceptor. A heating device may be assigned individually to each of the substrate carriers, to individually control the temperature of the flow zone arranged upstream of the substrate carrier. The invention also relates to a method with which heat is directed individually towards at least some of the flow zones by means of a separate heating device, wherein this may be done with many heating devices or with just one heating device. Heating devices which are each assigned to a substrate carrier in such manner that they direct supplementary heat towards the flow zones arranged upstream of the respective substrate carrier, are preferably controlled by a control device. But a control device of such kind may also control a single heating device in such manner that it supplies heat to the selected flow zone in time with the rotation of the susceptor.

Regarding further design features of the CVD reactor, reference is made to the document DE 10 2014 104 218 A1 cited in the introduction, the disclosure of which is incorporated into the disclosure of this application.

The method according to the invention is particularly suitable for depositing SiC layers onto substrates in a CVD reactor. However, the invention is also suitable to the deposition of GaN layers, GaAs layers, the deposition of GaP layers or mixed crystals from the elements Ga, N, As, P, In or other elements of main groups III and V. Further, the method includes not only the deposition of layers from elements of the main group IV but also the deposition of layers from elements of main groups II and VI.

### BRIEF DESCRIPTION OF THE DRAWINGS

In the following text, exemplary embodiments of the invention will be explained in greater detail with reference to the accompanying drawings. In the drawings:

FIG. 1 is a substantially schematic representation of a half section through a MOCVD reactor according to the invention,

FIG. 2 is a plan view of the susceptor 2 approximately along section line II-II,

FIG. 3 is a representation of a second exemplary embodiment according to FIG. 1,

FIG. 4 is a detail from a plan view of the susceptor 2 according to FIG. 2, but relating to the second embodiment,

FIG. 5 is a representation according to FIG. 1 of a third exemplary embodiment,

FIG. 6 is a schematic representation of a gas mixing system for supplying the gases,

FIG. 7 is a representation according to FIG. 1 of a fourth embodiment of the invention,

FIG. 8 is a representation according to FIG. 1 of a fifth embodiment of the invention, and

FIG. 9 is a representation according to FIG. 2 of a sixth embodiment of the invention.

### DETAILED DESCRIPTION

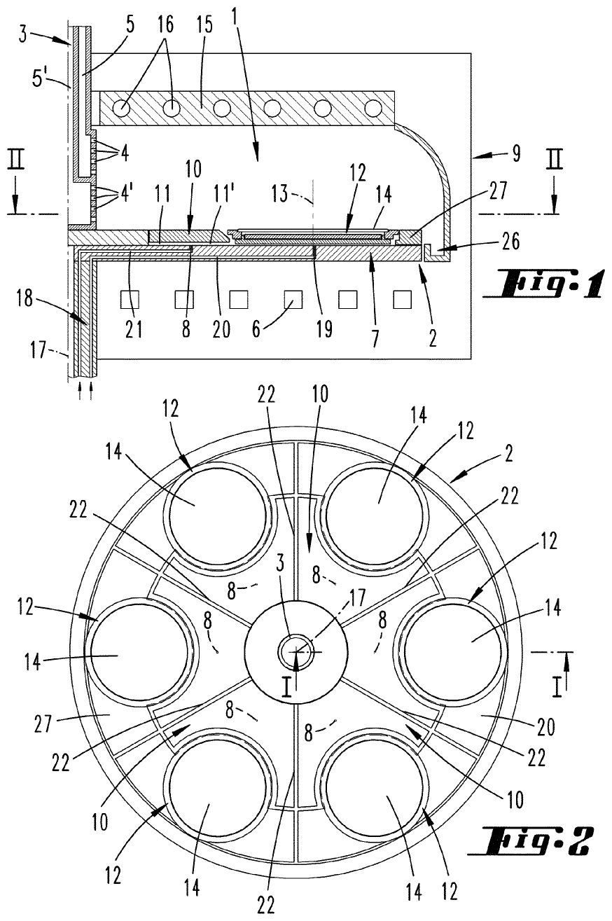

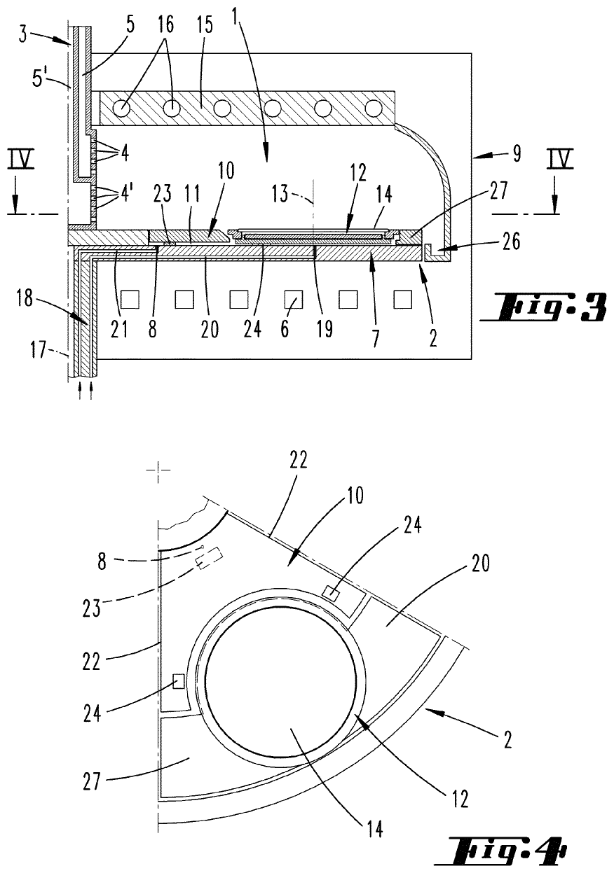

FIGS. 1 and 2 show schematically the elements essential for the explanation of a MOCVD reactor. Not represented is the housing of the MOCVD reactor, in which the assembly represented in FIGS. 1 and 2 is located. This is a housing which is insulated in gas-tight manner from the outside, into which a number of gas feed supply lines, liquid coolant supply lines, and a gas discharge line open. The gas supply lines not represented connect the supply line section 5, 5′ with a gas mixing system which includes reservoir containers, in which process gases and carrier gases are kept in stored in reserve. However, the process gases and the carrier gases may also be stored away from the gas mixing system, for example in a central gas supply. The central gas supply is then connected to the gas mixing system via supply lines. There, a carbon-containing gas and a silicon-containing gas, for example a hydrocarbon or a silicon-hydrogen compound are stored as process gases. In alternative methods AsH₃, NH₃, PH₃, trimethyl-gallium, trimethyl-indium, trimethyl-aluminium and other hydrides or organometallic compounds as well as doping agents may be stored there. These are fed via the supply line sections 5, 5′ using valves and mass flow controllers into a gas inlet member 3, where the process gases flow, separately from each other, out of the gas inlet regions 4, 4′, which are arranged vertically one above the other, into a process chamber 1. Three or more supply line sections 5, 5′ may be provided.

An energy supply is connected to a heating device which has one or more heating zones and which produces heat, which is fed into a main body 7 of a susceptor 2 from below. A permanent flow of heat from the heating device 6 to the cooled process chamber ceiling 15 is established, thereby creating a vertical temperature gradient inside the susceptor 2.

The main body 7 supports a large number of substrate carriers 12 arranged with even angular distribution. The substrate carriers 12 have a circular disc-like shape and are rotatable about an axis of rotation 13. They may be supported on a gas cushion, which also forces the substrate carrier 12 to rotate. It is formed by a gas which is fed through a feed channel 20 at a feed point 19 into a horizontal gap between underside of the substrate carrier 12 and upper side of the main body 7.

The surface regions of the main body 7 that are not covered by the substrate carriers 12, all parts of which may be made from graphite, quartz or a suitable metal, are covered by plates 10, 27. In the exemplary embodiment, the radially outer region is covered by an external plate 27.

The radially inner region is covered by a number of flow zone plates 10. In the exemplary embodiment, six flow zone plates 10 and six substrate carriers 12 are provided. In this context, one flow zone plate 10 is assigned individually to each substrate carrier 12. The flow zone plate 10 thus entirely fills the respective segment of the circular disc-shaped susceptor 2, in which a substrate carrier 12 is arranged. The entire surface between a substrate carrier 12 and the central gas inlet member 3 is occupied by a flow zone plate 10. The flow zone plates 10 adjoin each other, forming a joint 22 which extends in a radial direction. The joints 22 may be aligned with parting lines between two external plates 27. The joints 22 pass through the middle of an intermediate space between two adjacent substrate carriers 12. The flow zone plates 10 can be replaced individually.

The material of the flow zone plate 10 and/or the external plate 27 may be the same material from which the main body 7 is made. The central plate 8 preferably consists of quartz. On the other hand, the annular member, the substrate carrier 12 and the flow zone plate 10 are preferably made from graphite, in particular a coated graphite.

The flow zone plate 10 adjoins the substrate carriers 12, forming a vertical gap, and adjoins the gas inlet member 3 with a vertical gap. The flow zone plate 10 is kept at a vertical distance from the main body 7 by spacer means which are not represented, but which are known from the literature cited in the introduction. In this way, a horizontal gap is created, made up of a number of sections 11, 11′. The horizontal gap 11 may form a cooled section which is immediately adjacent to the gas inlet member 3, and a heated section which is immediately adjacent to the substrate carrier 12.

The underside of the flow zone plate 10 may be of flat design. In embodiments that are not shown, the underside of the flow zone plate 10 may have a stepped structure.

In radial direction between each substrate carrier 12 and the gas inlet member 3 there is at least one feed point 8 for a heat transfer gas, which is supplied to the feed point 8 via a feeder channel 21.

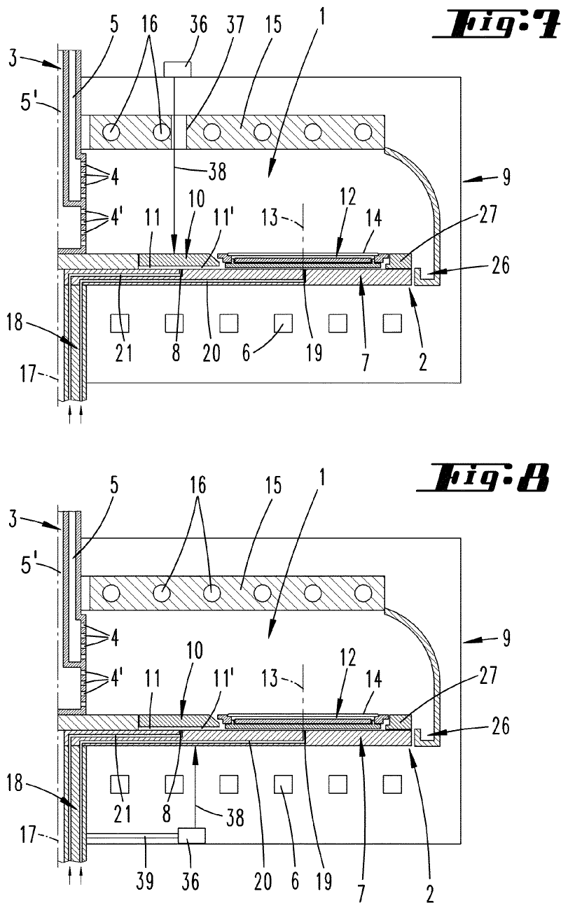

FIG. 6 is a schematic representation of a gas mixing system 27 with a total of six mass flow controllers 30, 31 arranged in pairs, of which only two are illustrated. By means of the mass flow controllers 30, 31, a heat transfer gas may be mixed from two inert gases, for example nitrogen and hydrogen, wherein each of the two inert gases has different specific heat conducting capabilities from the other. The gas mixture made available individually by the mass flow controllers 30, 31 is fed into one of a total of six feeder channels 21. A feeder channel 21 is assigned to each of the six flow zone plates 10 in the embodiment, so that an individual heat transfer gas flow relative to each substrate carrier 12 can be fed into the horizontal gap 11, 11′ between main body 7 and flow zone plate 10.

In the embodiment represented in FIG. 1, one section of the horizontal gap 11′ is located radially inside the feed point 8, and one section of the horizontal gap 11 is located downstream of the feed point 8. The heat transfer gas may be supplied through a column-like support member 18, which may be driven rotatably to rotate the susceptor 2 about an axis of rotation 17. Because gases can be fed into the feeder channels 21 independently of each other, each flow zone can be temperature controlled individually. Mixtures of two gases which differ from each other strongly with respect to their heat conductivity properties may be fed into the feeder channels 21 independently of one another. The heat conductivity property of section 11′ of the horizontal gap, into which the gas is fed, is changed by the mixing ratio of the two gases.

It is provided that individual flow zone plates 10 may be replaced by flow zone plates 10 with different heat conductivity properties. Accordingly, the apparatus according to the invention may contain flow zone plates 10 which differ from each other with respect to their heat conductivity properties and in particular are made from different materials.

In addition, the gas mixing system 27 is equipped with mass flow controllers 32, the number of which matches the number of substrate carriers 12. The gas made available by the mass flow controllers 32 is fed into feeder channels 20, which end at feed point 19.

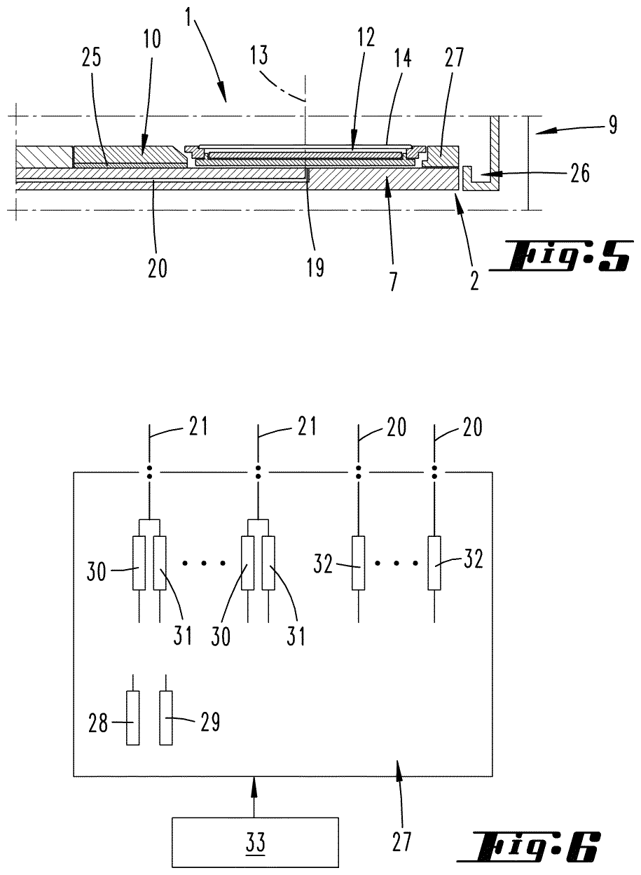

In the embodiment represented in FIGS. 3 and 4, the height of the horizontal gap 11 is defined by spacer elements 23, 24. The spacer elements may have heights of 0.5 mm, 0.75 mm and 1 mm or a multiple thereof. In particular, spacer elements 23, 24 may be used that are made from ceramic or another material. In particular, it is provided that a flow zone plate 10 is supported by three spacer elements 23, 24. The spacer elements 23, 24 may be selected from a group of spacer elements which have different thicknesses from each other, wherein the thicknesses of the spacer elements 23, 24 each differ by the same distance dimensions in the range between 0.1 and 0.5 mm, so that a finely graduated height adjustment of the horizontal gap 11 is possible.

The spacer elements 23, 24 of different thickness may be combined with flow zone plates 10 which have a different material thickness, so that the upper side of the flow zone plates 10 facing the process chamber 1 run at a uniform level. Neighbouring flow zone plates 10 may thus have different material thicknesses from each other and be supported on spacer elements 23, 24 of different heights.

However, it is also provided that the spacer elements 23, 24 are integrally, or at least fixedly connected to the underside of the flow zone plate 10. In this exemplary embodiment, horizontal gaps 11 with different heights may be obtained by replacing individual flow zone plates 10.

In the embodiment represented in FIG. 5, an intermediate space between the underside of the flow zone plate 10 and upper side of the main body 7 is filled by a heat transfer element 25. In this situation, the heat transfer element 25 may have the same footprint as the flow zone plate 10. Here too, it may be provided that the heat transfer elements 25 have material thicknesses that differ from each other and are combined with flow zone plates 10 having different material thicknesses, so that the upper sides of the flow zone plates 10 run at a uniform level. Different heat transfer elements 25 may be made out of different materials from each other. The materials differ in terms of their heat conductivity capability. A CVD reactor according to the invention may thus include heat transfer elements 25 of the same structure, which have different heat conductivity capabilities. It is also possible that different flow zone plates 10 may have different specific heat conductivity capabilities. In the embodiment represented in FIG. 5, it may not be necessary to feed a heat transfer gas in between flow zone plate 10 and main body 7.

FIG. 7 shows a fourth exemplary embodiment of the invention, in which the surface of flow zone plate 10 facing towards the process chamber can be heated actively. A heating device 36 is provided, which is a laser. The laser 36 is attached to the housing of the CVD reactor 9. The laser beam 38 produced by the laser 36 may be directed through an opening 37 in the process chamber ceiling 15 and onto the surface of the flow zone plate 10. The surface of the flow zone plate 10 is heated locally at the impingement point of the laser beam 38.

A control device (not shown) is provided, with which the laser 36 is synchronized with the rotating movement of the susceptor 2 in such manner that with each revolution of the susceptor 2 the same flow zone plates 10 in each case are heated locally by the laser beam 38. The laser 36 is thus switched on and off by the control device once or multiple times in time with the rotation of the susceptor 2.

But it is also possible to attach the laser 36 to the process chamber ceiling 15. Here too, the laser beam 38 may pass through an opening 37 in the process chamber ceiling 15. If the laser 36 is attached below the process chamber ceiling 15, this is not necessary.

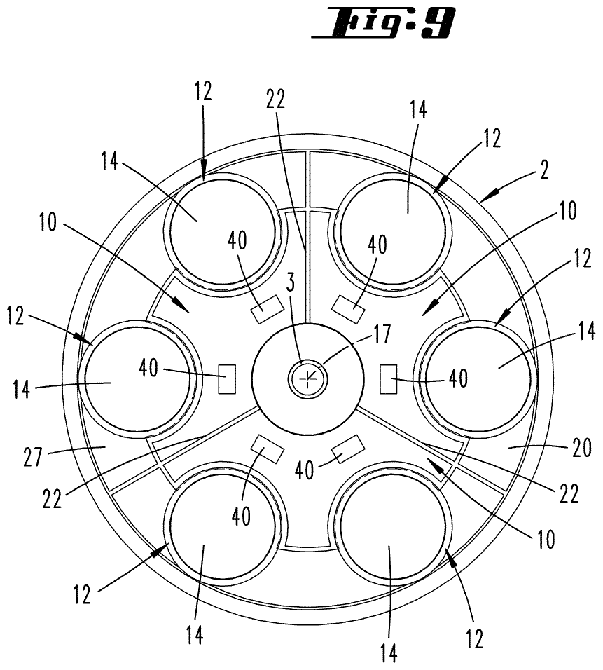

In the exemplary embodiment represented in FIG. 8, the susceptor 2 is heated from below with a local heating device 36. The local heating device 36 may be a laser that generates a laser beam 38 which impinges on the underside of the susceptor 2, and in particular on the underside of the main body 7, in the region of a flow zone plate 10. In this exemplary embodiment, it is provided that the laser 36 rotates together with the susceptor 2. To this end, it may be attached fixedly to the susceptor 2 or—as represented in FIG. 8—mounted on a shaft 18 with an arm 39.

In this exemplary embodiment, a number of heating devices 36 may be provided. In particular, it is provided that one heating device 36 is assigned individually to each substrate carrier 12.

In the exemplary embodiment represented in FIG. 9, a resistance heater 40 is assigned individually to each of the multiple substrate carriers 12. The resistance heater 40 is arranged upstream of the respective substrate carrier 12 and may be a part of the flow zone plate 10. However, the resistance heater 40 may also be arranged inside the main body 7 of the susceptor 2. It is further possible that the resistance heater 40 is arranged in a gap 11 between the flow zone plate 10 and the main body 7.

A control device is provided, with which the heating devices 36, 40 are operable and which supplies the heating devices 36, 40 with heating power in such manner that the surface temperatures of all substrates 14 supported on the substrate carriers 12 are substantially the same.

In the embodiments represented in FIGS. 7 to 9, it is not necessary for an individual flow zone plate 10 to be assigned to every single substrate carrier 12. In these embodiments, single flow zone plates 10 may also be assigned to a number of substrate carriers 12, as is the case in the prior art.

Regarding the design of the CVD reactor according to the invention or regarding the further features of the method, reference is made to document DE 10 2014 104 218 A1 cited in the introduction, the disclosure of which is incorporated in this disclosure in its entirety, in particular also for the purpose of including features in the claims.

The preceding notes are intended to explain the inventions presented in their entirety in the application, which advance the prior art at least with the following feature combinations, each also on its own merits, wherein two, more, or all of said feature combinations may also be combined, namely:

A CVD reactor, which is characterized in that a flow zone plate 10 separate from the other flow zone plates 10 is assigned to each of the multiple substrate carriers 12.

A CVD reactor, which is characterized in that a gap height of a horizontal gap 11, 11′ extending between the flow zone plate 10 and the main body 7 is adjustable.

A CVD reactor, which is characterized in that the gap height is adjustable by spacer elements 23, 24 that are different from each other, or by the replacement of a flow zone plate 10 with another flow zone plate 11.

A CVD reactor, which is characterized in that heat transfer elements 25 that are different from each other, with heat conductivity capabilities that are different from each other can be inserted between main body 7 of the flow zone plate 10.

A CVD reactor, which is characterized in that at least one feeder channel 20, 21 opens into a horizontal gap 11, 11′ between main body 7 and flow zone plate 10, through which a heat transfer gas, which is provided by a gas mixing device, can be fed into the horizontal gap 11, 11′.

A CVD reactor, which is characterized in that at least one feeder channel 20, 21 terminates before each substrate carrier 12 in the direction of flow, and an individualized mixture of a heat transfer gas consisting of two gases with heat conductivity capabilities that are different from each other can be fed into each of these feeder channels 20, 21, to which end each feeder channel 20, 21 has at least one mass flow controller 31, 32 for controlling a mass flow of the heat transfer gas.

A CVD reactor, which is characterized in that the flow zone plates 10 are arranged in a circular arrangement around the gas inlet member 3, and that the substrate carriers 12 are arranged radially outside a flow zone plate 10 in each case, that the flow direction is a radial direction, and that a gas outlet 26 is arranged radially outside the substrate carriers 12.

A method, which is characterized in that a flow zone plate 10 which is separate from the other flow zone plates 10 is assigned to each of the multiple substrate carriers 12.

A method, which is characterized in that a CVD reactor according to claims 1 to 7 is used, and the flow zone temperature is adjusted by the selection of suitable spacer elements 23, 24, suitable flow zone plates 10, suitable heat transfer element, and/or a suitable heat transfer gas.

A CVD reactor, which is characterized in that the flow zones can be heated individually.

A method, which is characterized in that heat is directed individually to at least some of the flow zones by means of a separate heating device 36, 40.

A CVD reactor or a method, which are characterized in that the flow zones are heatable with a flow zone heating device, wherein the flow zone heating device may be a laser 36 or a resistance heater 40.

A CVD reactor, which is characterized in that the flow zone heating device 36 is arranged immovably on the housing of the CVD reactor 9 or on the process chamber ceiling 15, and/or that the flow zone heating device 36 is connected in torque-proof manner to the susceptor 2 and or is attached underneath the susceptor 7.

All disclosed features are (per se, but also in combination with each other) essential to the invention. The disclosure content of the associated/accompanying priority documents (copy of the prior application) is herewith also incorporated in the disclosure of this application in its entirety, also for the purpose of including features of these documents in claims of the present application. Even without the features of a referenced claim, the subordinate claims, with the features thereof, characterize inventive further developments of the prior art that on their own merits, particularly for the purpose of submitting divisional applications based on said claims. The invention described in each claim may also include one or more of the features described in the preceding description, particularly those with associated reference numerals and/or in the list of reference numerals. The invention further relates to variants in which some of the features described in the preceding description are not realized, in particular if they are recognizably dispensable for the respective purpose or can be replaced by other means with technically equivalent function.

List of reference numerals

| | |
|---|---|
| 1 | Process chamber |
| 2 | Susceptor |
| 3 | Gas inlet member |
| 4 | Gas inlet region |
| 4′ | Gas inlet region |
| 5 | Supply line section |
| 5′ | Supply line section |
| 6 | Heating device |
| 7 | Main body |
| 8 | Feed point |
| 9 | CVD reactor |
| 10 | Flow zone plate |
| 11 | Horizontal gap |
| 11′ | Horizontal gap |
| 12 | Substrate carrier |
| 13 | Axis of rotation |
| 14 | Substrate |
| 15 | Process chamber ceiling |
| 16 | Cooling channel |
| 17 | Axis of rotation |
| 18 | Support member, shaft |
| 19 | Feed point |
| 20 | Feeder channel |
| 21 | Feeder channel |
| 22 | Joint |
| 23 | Spacer element |
| 24 | Spacer element |
| 25 | Heat transfer element |
| 26 | Gas outlet |
| 27 | Gas mixing system |
| 28 | Mass flow controller |
| 29 | Mass flow controller |
| 30 | Mass flow controller |
| 31 | Mass flow controller |
| 32 | Mass flow controller |
| 33 | Regulator |
| 36 | Laser heating element |
| 37 | Opening |
| 38 | Laser beam |
| 39 | Arm |
| 40 | Resistance heater |

What is claimed is:

1. A chemical vapor deposition (CVD) reactor (9), comprising:
a process chamber (1) with a ceiling (15);
a susceptor (2) that forms a floor of the process chamber (1), the susceptor (2) including a main body (7);
a gas inlet member (3) with at least one gas inlet region (4, 4′);
a first heating device (6) arranged under the susceptor (2) for creating a temperature difference between the main body (7) of the susceptor (2) and the ceiling (15) of the process chamber (1);
a plurality of substrate carriers (12) disposed on the main body (7) of the susceptor (2), each arranged downstream, in a flow direction of gas supplied by the gas inlet member (3), from the gas inlet member (3), and each for receiving a substrate (14); and
a plurality of flow zone plates (10) arranged between the gas inlet member (3) and the substrate carriers (12),
wherein for each of the flow zone plates (10), a flow zone temperature of a surface of the flow zone plate (10) facing the process chamber (1) is adjustable by adjusting a heat transfer medium located within a horizontal gap (11, 11′) separating the flow zone plate (10) from the main body (7),
wherein the heat transfer media arranged upstream, in the flow direction, of the substrate carriers (12) are each adjustable independently of one another, and
wherein each of the flow zone plates (10) is assigned to one of the substrate carriers (12).

2. The CVD reactor (9) of claim 1, wherein a gap height of the horizontal gap (11, 11′) is adjustable.

3. The CVD reactor (9) of claim 2, wherein the gap height is adjusted by replacing a first spacer element (23) with a second spacer element (24) that is different from the first spacer element (23), or by replacing a first one of the flow zone plates (10) with a second one of the flow zone plates (10).

4. The CVD reactor (9) of claim 1, further comprising replaceable heat transfer elements (25) arranged between the main body (7) and the flow zone plates (10).

5. The CVD reactor (9) of claim 1, further comprising at least one feeder channel (21) that opens into the horizontal gap (11, 11′), through which a heat transfer gas that is provided by a gas mixing device (27) is fed into the horizontal gap (11, 11′).

6. The CVD reactor (9) of claim 4, further comprising:
a feeder channel (21) that opens into the horizontal gap (11, 11′) upstream, in the direction of flow, of one of the substrate carriers (12);
a heat transfer gas consisting of two gases with different heat conducting capabilities from each other that is fed in to the feeder channel (21); and
a mass flow controller (31, 32) for controlling a mass flow of the heat transfer gas.

7. The CVD reactor (9) of claim 1, further comprising a gas outlet (26) arranged downstream, in the flow direction, of the substrate carriers (12),
wherein the flow zone plates (10) are arranged in a circular arrangement around the gas inlet member (3), and upstream, in the flow direction, of the substrate carriers (12).

8. The CVD reactor (9) of claim 1, further comprising a first flow zone and a second flow zone different from the first flow zone, wherein at least one of:
(i) a first one of the flow zone plates (10) is arranged in the first flow zone and a second one of the flow zone plates (10) is arranged in the second flow zone, wherein heat transfer properties of the first flow zone plate (10) are different from heat transfer properties of the second flow zone plate (10);
(ii) a first spacer element (23) is arranged in the first flow zone and a second spacer element (24) is arranged in the second flow zone, wherein a thickness of the first spacer element (23) is different from a thickness of the second spacer element (24); or
(iii) a first heat transfer element (25) is arranged in the first flow zone and a second heat transfer element (25) is arranged in the second flow zone, wherein a heat transfer property of the first heat transfer element (25) is different from a heat transfer property of the second heat transfer element (25).

9-11. (canceled)

12. A method for depositing a layer on substrates (14) in a chemical vapor deposition (CVD) reactor, the method comprising:
supporting the substrates (14) on substrate carriers (12);
feeding a process gas into a gas inlet member (3);
feeding the process gas from a gas inlet region (4, 4′) of the gas inlet member (3) into a process chamber (1), a floor of which is formed by a susceptor (2), which is heated by a first heating device (6) arranged under the susceptor (2) in such manner that a temperature difference is produced between a ceiling (15) of the process chamber (1) and the susceptor (2);
flowing the process gas in a flow direction towards the substrates (14), wherein the process gas is pre-decomposed above respective flow zone plates (10) in respective flow zones of the process chamber (1) between the gas inlet member (3) and a corresponding one of the substrate carriers (12);
forming the layer with products of decomposition of the process gas; and
for each of the flow zone plates (10), each being arranged immediately upstream of one of the substrate carriers (12) in the flow direction, adjusting a flow zone temperature of a surface of the flow zone plate (10) facing the process chamber (1) by adjusting a heat transfer medium located within a horizontal gap (11, 11′) separating the flow zone plate (10) from a main body (7) of the susceptor (2),
wherein each of the flow zone plates (10) is assigned to one of the substrate carriers (12).

13-15. (canceled)

16. The method of claim 12, wherein the flow zone temperature is further adjusted by one or more of:
(i) replacing a first spacer element (23) with a second spacer element (24);
(ii) replacing a first one of the flow zone plates (10) with a second one of the flow zone plates (10), or
(iii) replacing a first heat transfer element (25) with a second heat transfer element (25).

17. The method of claim 12, further comprising directing with a second heating device (36, 40) heat to individual ones of the flow zones in which the flow zone plates (10) are located.

18. The CVD reactor (9) of claim 1, further comprising a second heating device (36, 40) for heating individual ones of the flow zones in which the flow zone plates (10) are located.

19. The CVD reactor (9) of claim 18, wherein the second heating device (36, 40) comprises at least one of a laser (36) or a resistance heater (40).

20. The CVD reactor (9) of claim 19, wherein the second heating device (36) is arranged immovably on a housing of the CVD reactor (9) or on the ceiling (15) of the process chamber (1).

21. The CVD reactor (9) of claim 19, wherein the second heating device (36) is at least one of configured to rotate with the susceptor (2) or arranged under the susceptor (2).
